(19) United States
(12) Patent Application Publication
(10) Pub. No.: US 2011/0001135 A1
(43) Pub. Date: Jan. 6, 2011

(54) METHOD FOR MANUFACTURING SELF-ALIGNED THIN-FILM TRANSISTOR AND STRUCTURE THEREOF

(75) Inventors: Cheng Wei Chou, Tainan County (TW); Hsiao Wen Zan, Hsinchu County (TW); Chuang Chuang Tsai, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: National Chiao Tung University, Hsinchu (TW)

(21) Appl. No.: 12/549,471

(22) Filed: Aug. 28, 2009

(30) Foreign Application Priority Data
Jul. 1, 2009 (TW) 098122334

(51) Int. Cl. H01L 29/786; H01L 21/34

(52) U.S. Cl. 257/43; 438/104; 257/E21.459; 257/E29.296

(57) ABSTRACT

A method for manufacturing a self-aligned thin-film transistor (TFT) is described. Firstly, an oxide gate, a dielectric layer, and a photoresist layer are deposited on a first surface of a transparent substrate in sequence. Then, an ultraviolet light is irradiated on a second surface of the substrate opposite to the first surface to expose the photoresist layer, in which a gate manufactured by the oxide gate serves as a mask, and absorbs the ultraviolet light irradiated on the photoresist layer corresponding to the oxide gate. Then, the exposed photoresist layer is removed, and a transparent conductive layer is deposited on the unexposed photoresist layer and the dielectric layer. Then, a patterning process is executed on the transparent conductive layer to form a source and a drain, and an active layer is formed to cover the source, the drain, and the dielectric layer, so as to finish a self-aligned TFT structure.

### CROSS-REFERENCE TO RELATED APPLICATIONS

This non-provisional application claims priority under 35 U.S.C. §119(a) on Patent Application No(s). 098122334 filed in Taiwan, R.O.C. on Jul. 1, 2009, the entire contents of which are hereby incorporated by reference.

### BACKGROUND OF THE INVENTION

1. Field of the Invention

The present invention relates to a method for manufacturing a thin-film transistor (TFT), and more particularly to a method for manufacturing a self-aligned TFT and a structure thereof, which are capable of performing a self-aligned process by using a bottom gate structure.

2. Related Art

A TFT may be applied to a driver of a liquid crystal display (LCD), for example, applied to a driver of an active LCD, or applied to a static random access memory (SRAM) for serving as an active load. A photoelectric element manufactured by using an oxide TFT has characteristics of a simple manufacturing process and composite functions, for example, the photoelectric element is flexible and chic, the manufacturing process thereof is environmental protective, and the photoelectric element is manufactured and integrated in a large area. The characteristics of the oxide TFT are similar to characteristics of a common poly-silicon transistor, and the oxide TFT has a quite high stability, such that the oxide TFT is applied to manufacture various photoelectric elements.

For the manufacturing of the conventional TFT in the LCD, a TFT with a bottom gate structure is a recently commonly adopted technical solution in the industry. In the TFT with a bottom gate structure, a gate electrode manufactured on a substrate is used as a bottom gate. Then, a gate insulation layer, a gate dielectric layer, a semiconductor layer, a source/drain, a dielectric layer, and an active layer are sequentially formed through an exposing process (so-called photolithography process), so as to finish the manufacturing of the TFT.

However, the conventional TFT with a bottom gate structure encounters a serious problem that does not occurs to a TFT with a top gate structure, that is, it is difficult to implement a self-aligned process. That is to say, during a manufacturing process of forming the source/drain, the gate electrode serves as a mask. When the exposing process is executed, if a position of the mask is not accurately aligned with a preset position, the source/drain and the gate electrode are overlapped or non-uniformly contact with each other, such that a capacitance between the gate and the drain (Cgd) is non-uniform, which is a main reason for causing the mura phenomenon in the LCD.

In addition, the manufacturing procedures of the conventional TFT with a bottom gate structure are more complicated than that of the TFT with a top gate structure. A plurality of photolithography processes is required, and after the TFT with a bottom gate structure is finished, a larger parasitic capacitance exists, such that the whole characteristics of the TFT are deteriorated.

In order to solve the problems in the manufacturing process of the conventional TFT with a bottom gate structure, U.S. Pat. No. 6,338,988 discloses a method for fabricating self-aligned thin-film transistors, in which drain and source electrodes are defined by employing a single lithographic step, and the thin-film transistor has source and drain electrodes self-aligned to a gate electrode by employing a single lithographic step.

In U.S. Pat. No. 6,338,988, a first photoresist is patterned by employing the gate electrode as a mask for blocking light used to expose the first photoresist. However, a gate material disclosed in U.S. Pat. No. 6,338,988 is a metal material, such that a visible light penetrating the TFT may be shielded by the metal gate electrode, so that an opening ratio and a contrast ratio of the conventional TFT are greatly lowered.

### SUMMARY OF THE INVENTION

In view of the above problems, the present invention is a method for manufacturing a self-aligned TFT and a structure thereof, so as to solve the problems in the prior art that the manufacturing procedures of a conventional TFT with a bottom gate structure are too complicated, and an opening ratio and a contrast ratio of the conventional TFT are rather poor.

The present invention provides a method for manufacturing a self-aligned TFT and a structure thereof. The manufacturing method comprises the steps as follows. Firstly, a transparent substrate is provided, in which the transparent substrate has a first surface and a second surface opposite to each other. Then, an oxide gate is deposited on the first surface of the substrate, a dielectric layer is deposited on the oxide gate and the first surface of the substrate, and a photoresist layer is formed on the dielectric layer. Then, an ultraviolet light is irradiated on the second surface of the substrate, in which the ultraviolet light penetrates the substrate and the dielectric layer, and exposes the photoresist layer, and meanwhile, the oxide gate serves as a mask, and absorbs the ultraviolet light irradiated on the photoresist layer corresponding to the oxide gate. Then, the exposed photoresist layer is removed, and a transparent conductive layer is deposited on the unexposed photoresist layer and the dielectric layer. Then, a patterning process is executed on the transparent conductive layer, so as to form a source and a drain and expose a part of the dielectric layer. Finally, an active layer is formed to cover the source, the drain, and the dielectric layer, so as to form the self-aligned TFT structure.

In the method for manufacturing the self-aligned TFT and the structure thereof according to the present invention, the oxide gate having a high absorbing characteristic on the ultraviolet light serves as the bottom gate and the mask, and only exposes the photoresist layer other than that corresponding to the oxide gate, such that the source and the drain are accurately manufactured during the subsequent manufacturing procedures.

Furthermore, the oxide gate according to the present invention does not affect the penetration of a visible light of a backlight source, such that an opening ratio of an LCD having the TFT structure according to the present invention is greatly improved, thereby enhancing a contrast ratio of the LCD.

### BRIEF DESCRIPTION OF THE DRAWINGS

The present invention will become more fully understood from the detailed description given herein below for illustration only, and thus is not limitative of the present invention, and wherein:

FIG. 1 is a flow chart of steps according to a first embodiment of the present invention;

FIGS. 2A to 2F are schematic views of detailed steps according to the first embodiment of the present invention;

FIG. 3 is a spectrogram of a wavelength to an ultraviolet light absorption ratio of an oxide gate according to the present invention;

FIG. 4 is a flow chart of steps according to a second embodiment of the present invention; and

FIGS. 5A to 5G are schematic views of detailed steps according to the second embodiment of the present invention.

### DETAILED DESCRIPTION OF THE INVENTION

A self-aligned TFT according to the present invention may be applied to a TFT-LCD panel, an SRAM, and other devices. In the present invention, the TFT-LCD is taken as an example in the descriptions of the embodiments, but it is not limited here.

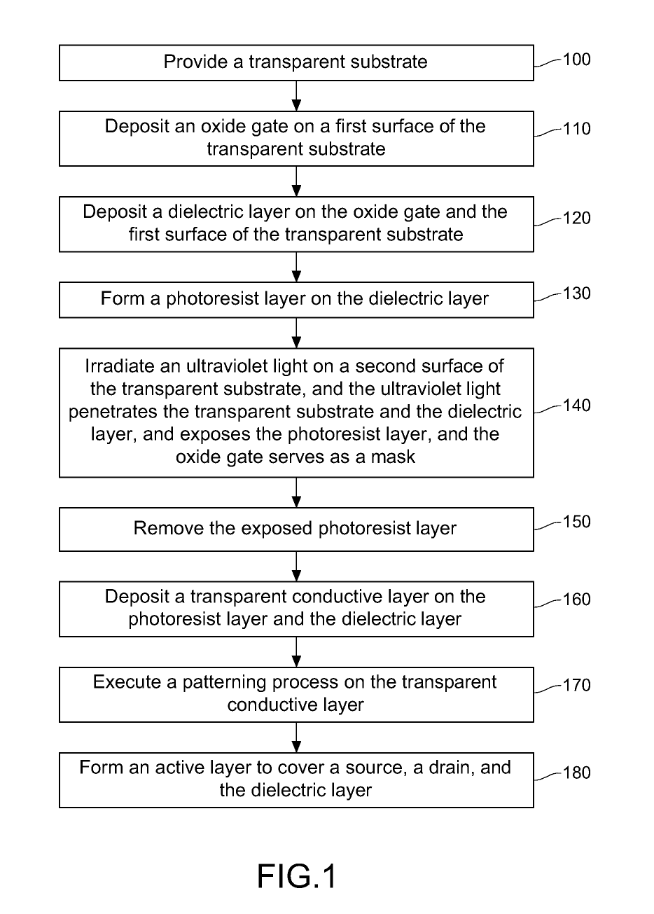

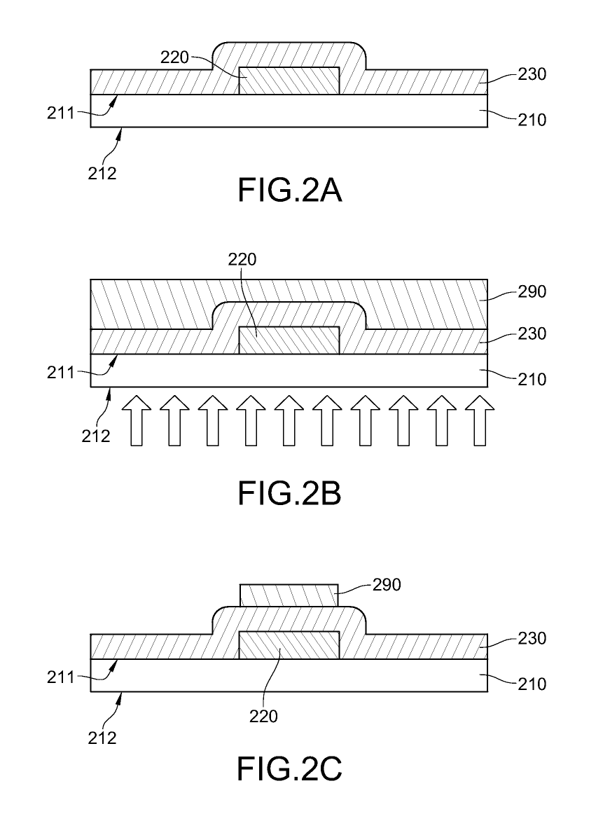

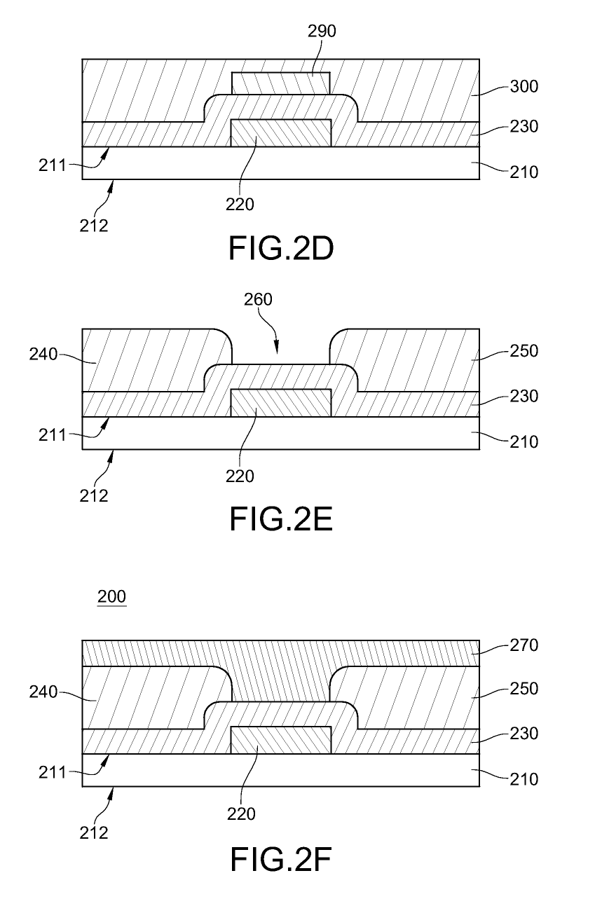

FIG. 1 and FIGS. 2A to 2F are respectively a flow chart of steps and schematic views of detailed steps according to a first embodiment of the present invention. Referring to FIG. 2A and the descriptions of the steps of FIG. 1, in a method for manufacturing a self-aligned TFT according to the first embodiment of the present invention, firstly, a transparent substrate 210 is provided (Step 100), in which the transparent substrate 210 has a first surface 211 and a second surface 212 opposite to each other (that is, respectively a top surface and a bottom surface of the transparent substrate 210). The transparent substrate 210 according to the present invention may be made of a quartz glass material or a plastic material, so as to respectively obtain a quartz glass substrate or a plastic substrate, but it is not limited here. Then, an oxide gate 220 is deposited on the first surface 211 of the transparent substrate 210 (Step 110), and the oxide gate 220 does not completely cover the transparent substrate 210, but only overlaps a part of the transparent substrate 210. The oxide gate 220 may be made of but not limited to, an indium tin oxide (ITO) material, a zinc oxide (ZnO) material, an indium zinc oxide (IZO) material, or an indium gallium zinc oxide (IGZO) material. Then, a dielectric layer 230 is deposited on the oxide gate 220 and the first surface 211 of the transparent substrate 210 (Step 120), in which the dielectric layer 230 according to the present invention is made of, but not limited to, an SiNₓ material or an SiO₂ material. Furthermore, the dielectric layer 230 according to the present invention is formed by chemical vapor deposition (CVD). However, it is known by those skilled in the art that the dielectric layer 230 may also be formed by physical vapor deposition (PVD) or a plasma manner, and it is not limited to the embodiments of the present invention.

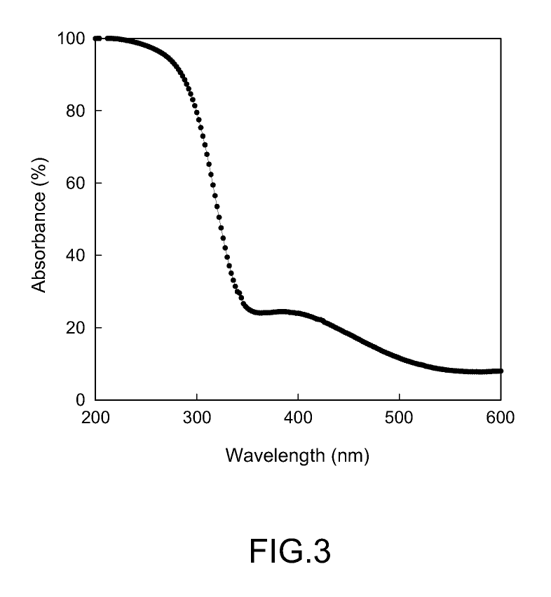

Referring to FIG. 2B and the descriptions of the steps of FIG. 1, a photoresist layer 290 is formed on the dielectric layer 230 (Step 130). The photoresist layer 290 according to the present invention is formed by coating a positive photoresist on the dielectric layer 230. Then, an ultraviolet light is irradiated on the second surface 212 of the transparent substrate 210, and the ultraviolet light penetrates the transparent substrate 210 and the dielectric layer 230, and exposes the photoresist layer 290 (Step 140). Referring to a spectrogram shown in FIG. 3, the oxide gate 220 according to the present invention has a high absorbing characteristic for a waveband with a wavelength between approximately 200 nm and 300 nm, that is, the oxide gate 220 according to the present invention is completely light transmissive in a wavelength section of a visible light, and has a high absorbing characteristic (that is, a low transmissive characteristic) in a wavelength section of the ultraviolet light. Therefore, the oxide gate 220 serves as a mask. In the step of irradiating the ultraviolet light according to the present invention, a wavelength of the ultraviolet light is between approximately 266 nm and 308 nm, and the oxide gate 220 absorbs the ultraviolet light irradiated on the photoresist layer 290 corresponding to the oxide gate 220, such that the ultraviolet light only penetrates the transparent substrate 210 and the dielectric layer 230, but cannot penetrate the oxide gate 220, and thus, the photoresist layer 290 corresponding to the oxide gate 220 is not exposed.

Referring to FIG. 2C and the descriptions of the steps of FIG. 1, the exposed photoresist layer 290 is removed (Step 150), that is, the photoresist layer 290 other than that corresponding to a position of the oxide gate 220 is completely removed. Referring to FIG. 2D, then, a transparent conductive layer 300 is deposited to cover the photoresist layer 290 and the dielectric layer 230 (Step 160), in which the transparent conductive layer 300 may be made of, but not limited to, the ITO material or the ZnO material.

Referring to FIG. 2E and the descriptions of the steps of FIG. 1, a patterning process is executed on the transparent conductive layer 300 (Step 170), so as to form a source 240 and a drain 250 separated from each other on the dielectric layer 230, and a window 260 is formed between the source 240 and the drain 250, so as to expose a part of the dielectric layer 230. A size of the window matches with that of the oxide gate 220, such that the formed source 240 and drain 250 are accurately disposed on preset positions in a self-aligned manner without any deviation.

Referring to FIG. 2F and the descriptions of the steps of FIG. 1, finally, an active layer 270 is formed to cover the source 240, the drain 250, and the dielectric layer 230 (Step 180), in which the active layer 270 is fully filled in the window 260, and contacts with the dielectric layer 230. The active layer 270 according to the present invention is made of an oxide thin film, and the oxide thin film may be made of, but not limited to, the ZnO material, the IZO material, or the IGZO material.

Through the above steps, the TFT 200 of a bottom gate type according to the first embodiment of the present invention as shown in FIG. 2F is finished. The TFT 200 comprises the transparent substrate 210, and the oxide gate 220, the dielectric layer 230, the source 240, the drain 250, and the active layer 270 disposed on the transparent substrate 210 in sequence.

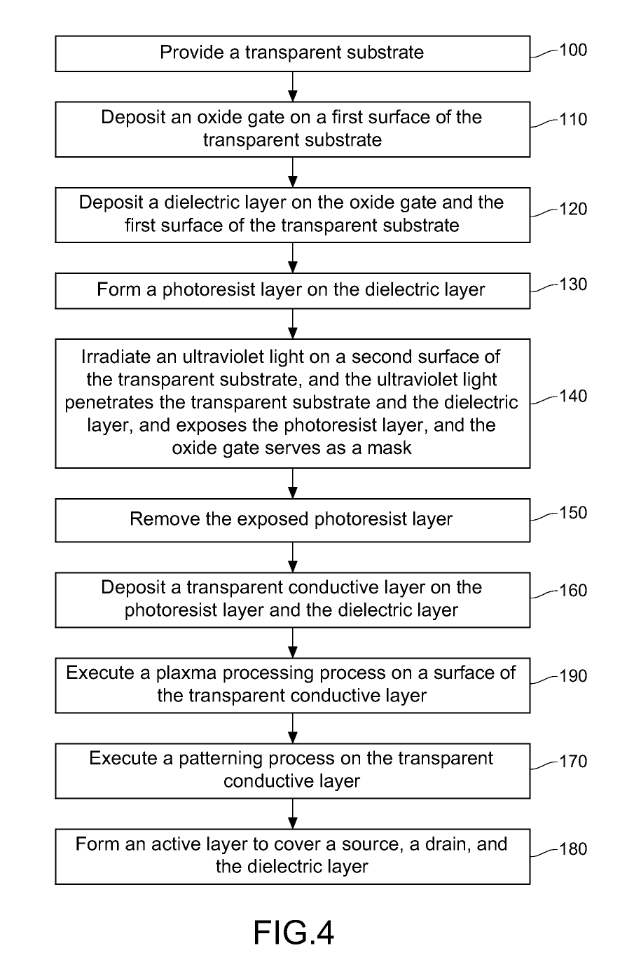

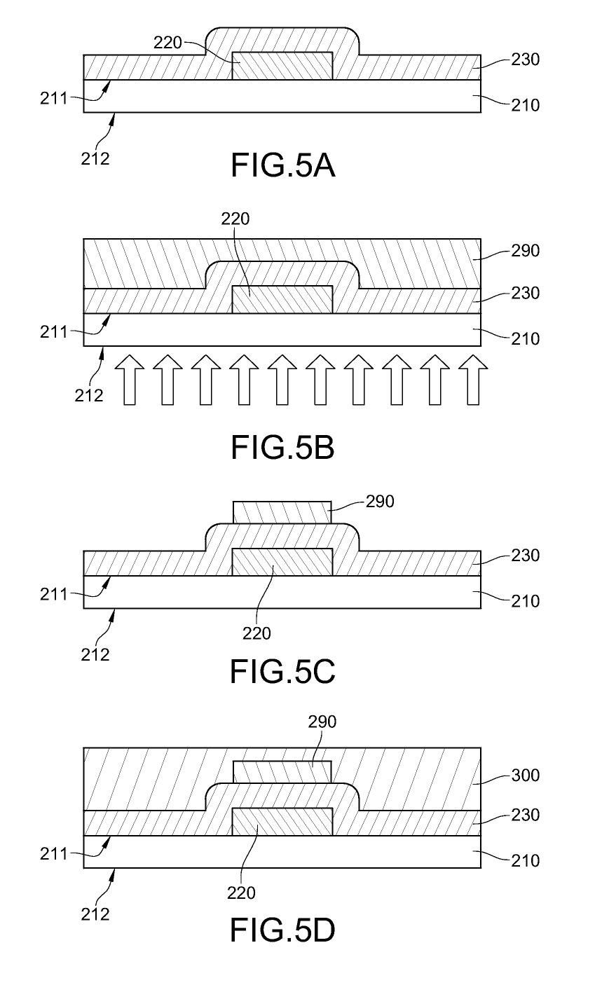

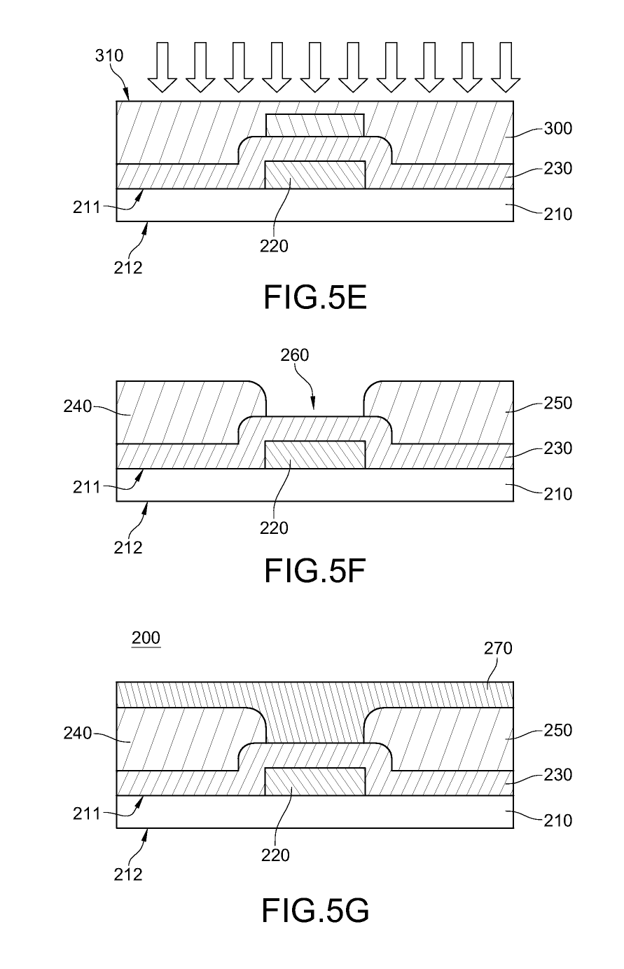

FIG. 4 and FIGS. 5A to 5G are respectively a flow chart of steps and schematic views of detailed steps according to a second embodiment of the present invention. Referring to FIG. 5A and the descriptions of the steps of FIG. 4, in a method for manufacturing a self-aligned TFT according to the second embodiment of the present invention, firstly, a transparent substrate 210 is provided (Step 100), in which the transparent substrate 210 has a first surface 211 and a second surface 212 opposite to each other (that is, respectively a top surface and a bottom surface of the transparent substrate 210). The transparent substrate 210 according to the present invention may be made of a quartz glass material or a plastic material, so as to respectively obtain a quartz glass substrate or a plastic substrate, but it is not limited here. Then, an oxide gate 220 is deposited on the first surface 211 of the transparent substrate 210 (Step 110), and the oxide gate 220 does not completely cover the transparent substrate 210, but only overlaps a part of the transparent substrate 210. The oxide gate 220 may be made of but not limited to, an ITO material, a ZnO material, an IZO material, or an IGZO material. Then, a dielectric layer 230 is deposited on the oxide gate 220 and the first surface 211 of the transparent substrate 210 (Step 120), in which the dielectric layer 230 according to the present invention is made of, but not limited to, an SiNₓ material or an SiO₂ material. Furthermore, the dielectric layer 230 according to the present invention is formed by CVD. However, it is known by those skilled in the art that, the dielectric layer 230 may also be formed by PVD or a plasma manner, and it is not limited to the embodiments of the present invention.

Referring to FIG. 5B and the descriptions of the steps of FIG. 4, a photoresist layer 290 is formed on the dielectric layer 230 (Step 130). The photoresist layer 290 according to the present invention is formed by coating a positive photoresist on the dielectric layer 230. Then, an ultraviolet light is irradiated on the second surface 212 of the transparent substrate 210, and the ultraviolet light penetrates the transparent substrate 210 and the dielectric layer 230, and exposes the photoresist layer 290 (Step 140). Referring to a spectrogram as shown in FIG. 3, the oxide gate 220 according to the present invention has a high absorbing characteristic for a waveband with a wavelength between approximately 200 nm and 300 nm, that is, the oxide gate 220 according to the present invention is completely light transmissive in a wavelength section of a visible light, and has a high absorbing characteristic (that is, a low transmissive characteristic) in a wavelength section of the ultraviolet light. Therefore, the oxide gate 220 serves as a mask. In the step of irradiating the ultraviolet light according to the present invention, a wavelength of the ultraviolet light is between approximately 266 nm and 308 nm, and the oxide gate 220 absorbs the ultraviolet light irradiated on the photoresist layer 290 corresponding to the oxide gate 220, such that the ultraviolet light only penetrates the transparent substrate 210 and the dielectric layer 230, but cannot penetrate the oxide gate 220, and thus, the photoresist layer 290 corresponding to the oxide gate 220 is not exposed.

Referring to FIG. 5C and the descriptions of the steps of FIG. 4, the exposed photoresist layer 290 is removed (Step 150), that is, the photoresist layer 290 other than that corresponding to a position of the oxide gate 220 is completely removed. Referring to FIG. 5D, then, a transparent conductive layer 300 is deposited to cover the photoresist layer 290 and the dielectric layer 230 (Step 160), in which the transparent conductive layer 300 may be made of, but not limited to, the ITO material or the ZnO material.

Referring to FIG. 5E and the descriptions of the steps of FIG. 4, after the transparent conductive layer 300 is deposited on the photoresist layer 290 and the dielectric layer 230 (Step 160), a plasma processing process is executed on a surface 310 of the transparent conductive layer 300 (Step 190), so as to reduce a contact resistance of the transparent conductive layer 300, thereby modifying the surface characteristic of the transparent conductive layer 300, which is helpful for subsequent processes.

Referring to FIG. 5F and the descriptions of the steps of FIG. 4, a patterning process is executed on the transparent conductive layer 300 (Step 170), so as to form a source 240 and a drain 250 separated from each other on the dielectric layer 230, and a window 260 is formed between the source 240 and the drain 250, so as to expose a part of the dielectric layer 230. The plasma processing process is executed on the surface 310 of the transparent conductive layer 300, so as to reduce the contact resistance of the transparent conductive layer 300, such that the element properties of the source 240 and the drain 250 formed on the surface 310 of the transparent conductive layer 300 are greatly improved. A size of the window matches with that of the oxide gate 220, such that the formed source 240 and drain 250 are accurately disposed on preset positions in a self-aligned manner without any deviation.

Referring to FIG. 5G and the descriptions of the steps of FIG. 4, finally, an active layer 270 is formed to cover the source 240, the drain 250, and the dielectric layer 230 (Step 180), in which the active layer 270 is fully filled in the window 260, and contacts with the dielectric layer 230. The active layer 270 according to the present invention is made of an oxide thin film, and the oxide thin film may be made of, but not limited to, the ZnO material, the IZO material, or the IGZO material.

Through the above steps, the TFT 200 of a bottom gate type according to the second embodiment of the present invention as shown in FIG. 5G is finished. The TFT 200 includes the transparent substrate 210, and the oxide gate 220, the dielectric layer 230, the source 240, the drain 250, and the active layer 270 disposed on the transparent substrate 210 in sequence.

In the method for manufacturing the self-aligned TFT and the structure thereof according to the present invention, the oxide gate serves as a bottom gate and a mask. The oxide gate has a high absorbing characteristic for the ultraviolet light, so as to shield the ultraviolet light irradiated on the photoresist layer corresponding to the oxide gate. Thus, the source and the drain are accurately manufactured in a self-aligned manner during the subsequent steps, without any deviation on the disposition positions thereof, and accordingly, the steps for manufacturing the TFT are greatly simplified.

Furthermore, the oxide gate according to the present invention has a high transmittance in the wavelength section of the visible light, and the configuration of the oxide gate does not affect the transmittance of the visible light from a backlight source, such that an opening ratio of an LCD having the TFT structure according to the present invention is greatly improved, thereby enhancing a contrast ratio of the LCD.

What is claimed is:

1. A method for manufacturing a self-aligned thin-film transistor (TFT), comprising:
providing a transparent substrate, wherein the transparent substrate has a first surface and a second surface opposite to each other;
depositing an oxide gate on the first surface of the transparent substrate;
depositing a dielectric layer on the oxide gate and the first surface of the transparent substrate;
forming a photoresist layer on the dielectric layer;
irradiating an ultraviolet light on the second surface of the transparent substrate, wherein the ultraviolet light penetrates the transparent substrate and the dielectric layer, and exposes the photoresist layer, and the oxide gate serves as a mask, and absorbs the ultraviolet light irradiated on the photoresist layer corresponding to the oxide gate;
removing the exposed photoresist layer;
depositing a transparent conductive layer on the photoresist layer and the dielectric layer;
executing a patterning process on the transparent conductive layer, so as to respectively form a source and a drain and expose a part of the dielectric layer; and
forming an active layer to cover the source, the drain, and the dielectric layer.

2. The method for manufacturing a self-aligned TFT according to claim 1, wherein after the step of depositing the transparent conductive layer on the photoresist layer and the dielectric layer, the method further comprises executing a plasma processing on a surface of the transparent conductive layer.

3. The method for manufacturing a self-aligned TFT according to claim 1, wherein the transparent substrate is made of a quartz glass material or a plastic material.

4. The method for manufacturing a self-aligned TFT according to claim 1, wherein the oxide gate is made of an indium tin oxide (ITO) material, a zinc oxide (ZnO) material, an indium zinc oxide (IZO) material, or an indium gallium zinc oxide (IGZO) material.

5. The method for manufacturing a self-aligned TFT according to claim 1, wherein the dielectric layer is made of an SiNₓ material or an SiO₂ material.

6. The method for manufacturing a self-aligned TFT according to claim 1, wherein the active layer is made of an oxide thin film.

7. The method for manufacturing a self-aligned TFT according to claim 6, wherein the oxide thin film is made of a ZnO material, an IZO material, or an IGZO material.

8. The method for manufacturing a self-aligned TFT according to claim 1, wherein the transparent conductive layer is made of an ITO material or a ZnO material.

9. The method for manufacturing a self-aligned TFT according to claim 1, wherein a wavelength of the ultraviolet light is between 266 nm and 308 nm.

10. A self-aligned thin-film transistor (TFT) structure, comprising:
a transparent substrate, having a first surface;
an oxide gate, disposed on the first surface of the transparent substrate, wherein the oxide gate serves as a mask, and has a characteristic of absorbing an ultraviolet light;
a dielectric layer, disposed on the oxide gate and the first surface of the transparent substrate;
a source and a drain, disposed on the dielectric layer, wherein a window is formed between the source and the drain, so as to expose a part of the dielectric layer; and
an active layer, covering the source, the drain, and the dielectric layer.

11. The self-aligned TFT structure according to claim 10, wherein the transparent substrate is a quartz glass substrate or a plastic substrate.

12. The self-aligned TFT structure according to claim 10, wherein the oxide gate is made of an indium tin oxide (ITO) material, a zinc oxide (ZnO) material, an indium zinc oxide (IZO) material, or an indium gallium zinc oxide (IGZO) material.

13. The self-aligned TFT structure according to claim 10, wherein the dielectric layer is made of an SiNₓ material or an SiO₂ material.

14. The self-aligned TFT structure according to claim 10, wherein the active layer is made of an oxide thin film.

15. The self-aligned TFT structure according to claim 14, wherein the oxide thin film is made of a ZnO material, an IZO material, or an IGZO material.

16. The self-aligned TFT structure according to claim 10, wherein the source and the drain are made of an ITO material or a ZnO material.

17. The self-aligned TFT structure according to claim 10, wherein a wavelength of the ultraviolet light is between 266 nm and 308 nm.
